(19) United States
(12) Patent Application Publication
(10) Pub. No.: US 2013/0045591 A1
(43) Pub. Date: Feb. 21, 2013

(54) NEGATIVE TONE DEVELOP PROCESS WITH PHOTORESIST DOPING

(71) Applicants: JUDY BROWDER SHAW, LEONARD, TX (US); SCOTT WILLIAM JESSEN, ALLEN, TX (US)

(72) Inventors: JUDY BROWDER SHAW, LEONARD, TX (US); SCOTT WILLIAM JESSEN, ALLEN, TX (US)

(73) Assignee: TEXAS INSTRUMENTS INCORPORATED, Dallas, TX (US)

(21) Appl. No.: 13/585,924

(22) Filed: Aug. 15, 2012

Related U.S. Application Data
(60) Provisional application No. 61/523,565, filed on Aug. 15, 2011.

(51) Int. Cl. G03F 7/20; H01L 21/311; H01L 21/266

(52) U.S. Cl. 438/514; 430/319; 438/700; 257/E21.346; 257/E21.249

(57) ABSTRACT

A method of semiconductor processing includes coating a top surface of a substrate having a semiconductor surface with a positive photoresist layer. The positive photoresist layer is exposed using a reticle or a mask that defines a pattern. The positive photoresist layer is doped by introducing at least one material modifying species after exposing. The positive photoresist layer is developed with a negative tone developer to form a patterned positive photoresist layer which provides masked portions of the top surface and unmasked portions of the top surface. A selective process is then performed to the unmasked portions of the top surface.

### CROSS REFERENCE TO RELATED APPLICATIONS

This application claims the benefit of Provisional Application Ser. No. 61/523,565 entitled “Method for Improving Resist Etch Resistance and Line Edge Roughness for a Negative Tone Development Process Using Implant Deposition”, filed Aug. 15, 2011, which is herein incorporated by reference in its entirety.

### FIELD

Disclosed embodiments relate to semiconductor processing comprising photolithography including negative tone develop (NTD) processing of integrated circuit substrates (e.g., wafers).

### BACKGROUND

Semiconductor processing to form integrated circuits (ICs) includes a plurality of levels that are printed on a semiconductor surface of a substrate (e.g., wafer) using photolithography which comprises patterning photoresist on the semiconductor surface. Photoresists can be classified into two groups, positive photoresists and negative photoresists.

After a wafer has been coated with photoresist and is subjected to soft baking, the photoresist undergoes exposure to radiation, typically ultraviolet (UV) radiation, that produces a pattern image in the photoresist. The pattern is formed on the wafer using a reticle or a mask, which defines which areas of the photoresist surface will be exposed to radiation and those that will be covered and thus not exposed to radiation. The chemical properties of the photoresist regions struck by incident radiation change in a manner that depends on the type of photoresist used. Development using an appropriate developer solution follows photoresist exposure to leave behind a photoresist pattern on the wafer which will serve as the physical mask that covers areas on the wafer that need to be protected from subsequent processing, such as for etching, implantation, lift-off, etc.

### SUMMARY

Disclosed embodiments relate to semiconductor processing comprising photolithography including negative tone develop (NTD) processing of integrated circuit (IC) substrates (e.g., wafers) using a positive photoresist. A positive photoresist is used to achieve the tone reversal to achieve the desired resolution capability, such as 193 nm imaging for advanced nodes (20 nm and beyond) in order to achieve smaller print critical dimensions (CDs) with sufficient lithography margin since NTD “washes out” the non-exposed photoresist, leaving exposed photoresist behind after NTD.

Disclosed embodiments recognize the exposed photoresist resist left behind after NTD has degraded properties, including degraded line edge roughness and etch resistance/selectivity, and may also have a smaller remaining film thickness as compared to before NTD. Disclosed embodiments reflect the discovery that by adding at least one material modifying dopant species to the photoresist after NTD improves the line edge roughness, etch resistance/selectivity, and may also increase the thickness of the photoresist. Disclosed embodiments thus reduce weaknesses in NTD processes.

### BRIEF DESCRIPTION OF THE DRAWING

Reference will now be made to the accompanying drawing.

FIG. 1 is a flow chart that shows steps in an example method for semiconductor processing comprising photolithography including NTD, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

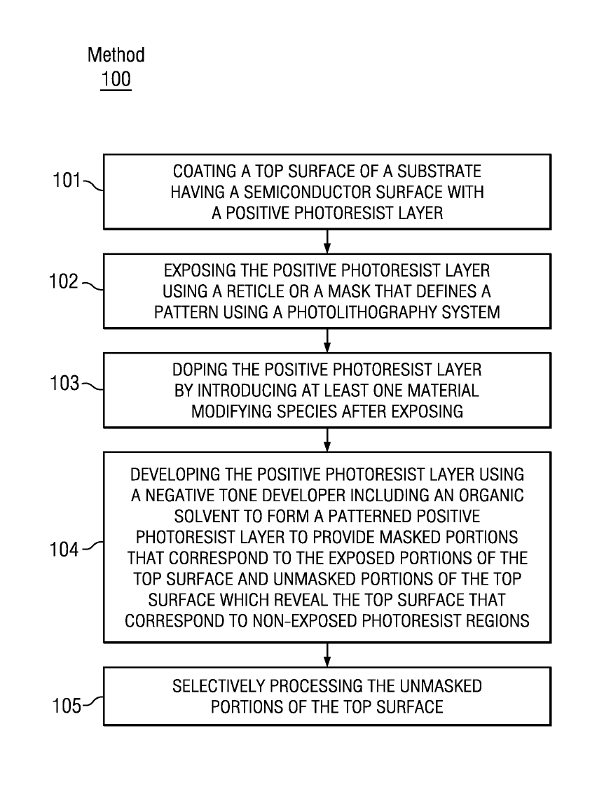

FIG. 1 is a flow chart that shows steps in an example method 100 of semiconductor processing comprising photolithography including NTD, according to an example embodiment. Step 101 comprises coating a top surface of a substrate having a semiconductor surface with a positive photoresist layer. The substrate is generally in wafer form, and can generally comprise any type of substrate, including silicon or a silicon-germanium substrate, a III-V substrate, or a II-VI substrate. The top surface being coated can be the semiconductor surface of the substrate (e.g., a silicon surface), or a layer thereon, such as a metal layer, semiconductor layer, or a dielectric layer.

The term “photoresist” as used herein refers to a light sensitive material, while the term “positive photoresist” refers to a photoresist material that that when exposed to light (typically UV light) becomes insoluble to a negative tone developer, while the portion of the photoresist that is non-exposed (or exposed less) becomes soluble to the negative tone developer.

Step 102 comprises exposing the positive photoresist layer using a reticle or a mask that defines a pattern using a photolithography system, generally comprising a stepper or scanner, having a light source and optics. In one embodiment the exposing comprises immersion lithography where the conventional air gap between the final lens and the wafer surface is filled with a liquid medium that has a refractive index greater than one, such as by using water. For immersion lithography, the light source can comprise a 193 nm laser.

In one embodiment, a double exposure is used. As known in the art, double exposure is a sequence of two separate exposures of the same photoresist layer using two different reticle or masks. In double patterning techniques, each reticle or mask would correspond to a subset of the layer pattern.

Step 103 comprises doping the positive photoresist layer by introducing at least one material modifying species after exposing. The doping can comprise a gas cluster ion beam (GCIB) process, an ion implant process, or a plasma immersion ion implant process. The material modifying species can comprise species such as Si, Ar, B, C, Ge, N, P, As, O, S, F, Cl, or Br, or combinations therefor. The dopant dose is generally between 2×10¹⁴ cm⁻² to 3×10¹⁶cm⁻². In the case of ion implantation, the implant energy is generally from 3 keV to 20 keV, with an upper bound in implant energy limited by the dopant range, and the stopping power and thickness of the photoresist when the dopant is not desired to reach the top surface of the substrate. In one embodiment the substrate is rotated at least once to provide a portion of the dopant implanted at one angle and another portion implanted at another angle.

Step 104 comprises developing the positive photoresist layer using a negative tone developer including an organic solvent to form a patterned positive photoresist layer to provide masked portions that correspond to the exposed portions of the top surface and unmasked portions of said top surface which reveal the top surface that correspond to non-exposed photoresist regions. The term “negative tone developer” refers to a developer that selectively dissolves and removes exposed areas that received an exposure dose below a predetermined threshold exposure dose value, which may be contrasted with a “positive tone developer” which refers to a developer that selectively dissolves and removes the exposed area of photoresist above a predetermined threshold value exposure dose. The organic solvent can comprise a solvent such as a ketone-based solvent, ester-based solvent, alcohol-based solvent, amide-based solvent, ether-based solvent or hydrocarbon-based solvent.

The doping (step 103) can take place before or after the developing (step 104). Step 105 comprises selectively processing the unmasked portions of the top surface. The selective processing can comprise etching (e.g., plasma etching) or ion implanting. After the selective processing, the photoresist can then be stripped, and the substrate (e.g., wafer) moved to the next step.

Disclosed embodiments can be used to form semiconductor die that may integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method of semiconductor processing, comprising:
coating a top surface of a substrate having a semiconductor surface with a positive photoresist layer;
exposing said positive photoresist layer using a reticle or a mask that defines a pattern;
doping said positive photoresist layer by introducing at least one material modifying species after said exposing;
developing said positive photoresist layer with a negative tone developer to form a patterned positive photoresist layer to provide masked portions of said top surface and unmasked portions of said top surface which expose said top surface, and
selectively processing said unmasked portions of said top surface.

2. The method of claim 1, wherein said doping is before said developing.

3. The method of claim 1, wherein said doping is after said developing.

4. The method of claim 1, wherein said material modifying species comprises Si, Ar, B, C, Ge, N, P, As, O, S, F, Cl, or Br, or combinations thereof.

5. The method of claim 1, wherein a dose for said doping is between 2×10¹⁴ cm⁻² and 3×10¹⁶cm⁻².

6. The method of claim 1, wherein said selectively processing comprises etching or ion implanting.

7. The method of claim 1, wherein said doping comprises a gas cluster ion beam (GCIB) process, an ion implant process, or a plasma immersion ion implant process.

8. The method of claim 1, wherein said exposing comprises immersion lithography.

9. The method of claim 1, wherein said method comprises a double exposure method including performing said exposing a second time with changing said reticle or said mask.

10. A method of semiconductor processing, comprising:
coating a top surface of a substrate comprising silicon with a positive photoresist layer;
exposing said positive photoresist layer using a reticle or a mask that defines a pattern; wherein said exposing comprises immersion lithography;
ion implanting said positive photoresist layer to introduce at least one material modifying species after said exposing;
developing said positive photoresist layer with a negative tone developer to form a patterned positive photoresist layer to provide masked portions of said top surface and unmasked portions of said top surface which expose said top surface, and
selectively processing said unmasked portions of said top surface.

11. The method of claim 10, wherein said doping is before said developing.

12. The method of claim 10, wherein said doping is after said developing.

13. The method of claim 10, wherein a dose for said ion implanting is between 2×10¹⁴cm⁻² and 3×10¹⁶cm⁻².
